(19) United States
(12) Patent Application Publication
(10) Pub. No.: US 2025/0151527 A1
(43) Pub. Date: May 8, 2025

(54) DISPLAY DEVICE

(71) Applicant: LG Display Co., Ltd., Seoul (KR)

(72) Inventors: SeHong PARK, Paju-si (KR); SeoHyun NAM, Paju-si (KR); InGoo LEE, Paju-si (KR); YoungNam LIM, Paju-si (KR); Hyeonhye YU, Paju-si, Gyeonggi-do (KR)

(73) Assignee: LG Display Co., Ltd., Seoul (KR)

(21) Appl. No.: 18/915,904

(22) Filed: Oct. 15, 2024

(30) Foreign Application Priority Data
Nov. 7, 2023 (KR) 10-2023-0152306

(51) Int. Cl. H10K 59/122; H10K 59/38; H10K 59/80

(52) U.S. Cl. CPC H10K 59/122; H10K 59/80521; H10K 59/878; H10K 59/879; H10K 59/38

(57) ABSTRACT

A display device may include: a substrate; a plurality of subpixels each of which includes an emitting area and a non-emitting area; an overcoat layer disposed over the substrate, and having a concave part located between the emitting areas; a first electrode layer disposed on a periphery of the concave part; a metal pattern layer disposed to cover a sloped portion of the concave part; and a bank layer covering the concave part, and disposed on the metal pattern layer. It is possible to improve light extraction efficiency.

### CROSS-REFERENCE TO RELATED APPLICATIONS

This application claims the benefit of and priority to Korean Patent Application No. 10-2023-0152306 filed on Nov. 7, 2023, the entire contents of which are incorporated herein by reference for all purposes as if fully set forth herein.

### BACKGROUND

### 1. Technical Field

Example embodiments of the present disclosure relate to a display device.

### 2. Description of the Related Art

Display devices are being widely used as display screens of a notebook computer, a tablet computer, a smartphone, a portable display device and a portable information device, in addition to the display device of a television or a monitor.

Display devices may be classified into a reflective display device and a light emitting display device. The reflective display device is a type of display device in which natural light or light emitted from an external lighting of the display device is reflected on the display device to display information, and the light emitting display device is a type of display device in which a light emitting element or light source is built in the display device and information is displayed using light generated from the built-in light emitting element or light source.

The description of the related art should not be assumed to be prior art merely because it is mentioned in or associated with this section. The description of the related art includes information that describes one or more aspects of the subject technology, and the description in this section does not limit the invention.

### SUMMARY

In the case of a conventional display device, light emitted from a light emitting layer and traveling laterally may not be extracted to the outside because a second electrode layer, which is a reflective electrode, is flat but may be extinguished in a bank layer, reducing light efficiency, and due to reflection by external light, a problem arises in that visibility and contrast ratio deteriorate.

Example embodiments of the present disclosure may provide a display device capable of improving light extraction efficiency.

Example embodiments of the present disclosure may provide a display device capable of low-power driving by improving light extraction efficiency.

According to example embodiments of the present disclosure, a display device may include: a substrate; a plurality of subpixels each of which includes an emitting area and a non-emitting area; an overcoat layer disposed over the substrate, and having a concave part located between emitting areas; a first electrode layer disposed on a periphery of the concave part; a metal pattern layer disposed to cover a sloped portion of the concave part; and a bank layer covering the concave part, and disposed on the metal pattern layer.

According to example embodiments of the present disclosure, a display device may include: a substrate; a plurality of subpixels each of which includes an emitting area and a non-emitting area; an overcoat layer disposed over the substrate, and having a concave part located between emitting areas; a first electrode layer disposed on a periphery of the concave part; and a bank layer covering a sloped portion of the concave part, wherein the overcoat layer includes a first overcoat layer which is disposed over the substrate and a second overcoat layer which is disposed on the first overcoat layer and includes the sloped portion of the concave part, and wherein a refractive index of the second overcoat layer is greater than a refractive index of the first overcoat layer.

According to example embodiments of the present disclosure, a display device may include: a substrate; a plurality of subpixels each of which includes an emitting area and a non-emitting area; an overcoat layer disposed over the substrate, and having a concave part located between emitting areas; a first electrode layer disposed on the overcoat layer; a bank layer covering at least a portion of the first electrode layer and at least a portion of the concave part; and a light emitting layer covering at least a part of the first electrode layer and at least a part of the bank layer, wherein at least a part of the light emitting layer may overlap the concave part.

According to the example embodiments of the present disclosure, it is possible to provide a display device capable of improving light extraction efficiency.

According to the example embodiments of the present disclosure, it is possible to provide a display device capable of low-power driving by improving light extraction efficiency.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a diagram showing a schematic system configuration of a display device according to example embodiments of the present disclosure.

FIG. 2 is a view illustrating a schematic planar structure of a pixel structure disposed in a display panel of a display device according to an example embodiment of the present disclosure.

FIG. 3 is an example of a cross-sectional view taken along the line A-A′ of FIG. 2.

FIG. 4 is a view illustrating a schematic planar structure of a pixel structure disposed in a display panel of a display device according to another example embodiment of the present disclosure.

FIG. 5 is an example of a cross-sectional view taken along the line B-B′ of FIG. 4.

FIG. 6 is a view illustrating a schematic planar structure of a pixel structure disposed in a display panel of a display device according to still another example embodiment of the present disclosure.

FIG. 7 is an example of a cross-sectional view taken along the line C-C′ of FIG. 6.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, section, member, part, region, area, portion, or the like) “is engaged” with another element may be understood, for example, as that the element may be either directly or indirectly engaged with the another element. The term “is engaged” or similar expressions may refer to a term such as “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between them, unless otherwise specified. The element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Moreover, “at least a portion,” “at least a part,” or “at least some” of an element can represent (i) a portion of the element, (ii) one or more portions of the element, or (iii) the element, or all portions of the element.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

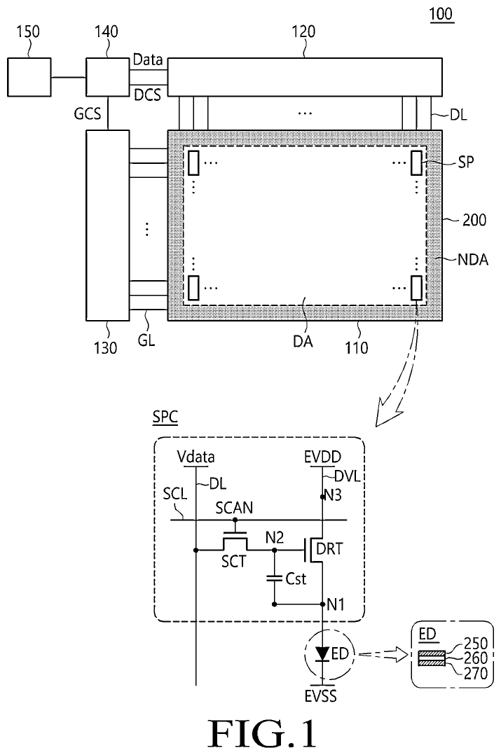

FIG. 1 is a diagram showing a schematic system configuration of a display device according to example embodiments of the present disclosure.

Referring to FIG. 1, the driving system of the display device 100 according to the example embodiments of the present disclosure may include a display panel 110 and a display driving circuit for driving the display panel 110.

The display panel 110 may include a display area DA in which an image is displayed and a non-display area NDA in which an image is not displayed.

The display panel 110 may include a plurality subpixels SP which are disposed on a substrate 200 to display an image.

The display panel 110 may include a plurality of signal wirings which are disposed on the substrate 200.

For example, the plurality of signal wirings may include data lines DL, gate lines GL, driving voltage lines DVL, etc.

Each of the plurality of data lines DL may be disposed to extend in a first direction (a column direction in an example or a row direction in another example), and each of the plurality of gate lines GL may be disposed to extend in a second direction (a row direction in an example or a column direction in another example) orthogonal to the first direction.

The display driving circuit may include a data driving circuit 120, a gate driving circuit 130 and a controller 140.

The controller 140 may control the data driving circuit 120 and the gate driving circuit 130.

The data driving circuit 120 may output data signals corresponding to an image signal to the plurality of data lines DL.

The gate driving circuit 130 may generate gate signals and output the gate signals to the plurality of gate lines GL.

The controller 140 may convert input image data inputted from an external host 150 to suit a data signal format employed in the data driving circuit 120, and may supply the converted image data to the data driving circuit 120.

The data driving circuit 120 may include at least one source driver integrated circuit.

For example, each source driver integrated circuit may be connected to the display panel 110 in a tape automated bonding (TAB) method, may be connected to the bonding pads of the display panel 110 in a chip-on-glass (COG) or chip-on-panel (COP) method, or may be connected to the display panel 110 by being implemented in a chip-on-film (COF) method.

The gate driving circuit 130 may be connected to the display panel 110 in a tape automated bonding (TAB) method, may be connected to the bonding pads of the display panel 110 in a COG or COP method, may be connected to the display panel 110 according to a COF method, or may be formed in the non-display area NDA of the display panel 110 in a gate-in-panel (GIP) type.

Referring to FIG. 1, in the display device 100 according to the example embodiments of the present disclosure, each subpixel SP may include a light emitting element ED and a pixel driving circuit SPC for driving the light emitting element ED.

The pixel driving circuit SPC may include a driving transistor DRT, a scan transistor SCT and a storage capacitor Cst.

The driving transistor DRT may drive the light emitting element ED by controlling current flowing to the light emitting element ED.

The scan transistor SCT may transfer a data voltage Vdata to a second node N2, which is the gate node of the driving transistor DRT.

The storage capacitor Cst may be configured to maintain a voltage for a predetermined period of time.

The light emitting element ED may include a first electrode layer 250, a second electrode layer 270 and a light emitting layer 260.

The light emitting layer 260 is located between the first electrode layer 250 and the second electrode layer 270.

The first electrode layer 250 may be a pixel electrode which is involved in the formation of the light emitting element ED of each subpixel SP, and may be electrically connected to a first node N1 of the driving transistor DRT.

The second electrode layer 270 may be a common electrode which is involved in the formation of the light emitting elements ED of all subpixels SP, and may be applied with a base voltage EVSS.

For example, the light emitting element ED may be an organic light emitting diode (OLED), an inorganic-based light emitting diode (LED) or a quantum dot (QD) light emitting element.

When the display device 100 according to the example embodiments of the present disclosure is an OLED display, each subpixel SP may include, as a light emitting element, an organic light emitting diode (OLED).

When the display device 100 according to the example embodiments of the present disclosure is a quantum dot (QD) light emitting element, each subpixel SP may include a light emitting element made of quantum dots (QD).

When the display device 100 according to the example embodiments of the present disclosure is a micro LED display, each subpixel SP may include, as a light emitting element, a micro light emitting diode (micro LED) which emits light on its own and is made on the basis of an inorganic material.

The driving transistor DRT as a transistor for driving the light emitting element ED may include the first node N1, the second node N2 and a third node N3.

The first node N1 may be a source or drain node, and may be electrically connected to the first electrode layer 250 of the light emitting element ED.

The second node N2 may be the gate node, and may be electrically connected to a source or drain node of the scan transistor SCT.

The third node N3 may be a drain or source node, and may be electrically connected to a driving voltage line DVL which supplies a driving voltage EVDD.

In the present disclosure, it will be described as an example that the first node N1 is a source node and the third node N3 is a drain node.

The scan transistor SCT may switch the connection between a data line DL and the second node N2 of the driving transistor DRT.

In response to a scan signal SCAN supplied from a scan line SCL as a type of gate line GL, the scan transistor SCT may control the connection between the second node N2 of the driving transistor DRT and a corresponding data line DL among the plurality of data lines DL.

The storage capacitor Cst may be configured between the first node N1 and the second node N2 of the driving transistor DRT.

The structure of the subpixel SP shown in FIG. 1 is nothing but a mere example for explanation, and may further include at least one transistor or at least one capacitor.

Each of the plurality of subpixels SP may have the same structure, and some of the plurality of subpixels SP may have a different structure.

Each of the driving transistor DRT and the scan transistor SCT may be an n-type transistor or a p-type transistor.

The display device 100 according to the example embodiments of the present disclosure may have a top emission structure or a bottom emission structure.

Hereinafter, in the present disclosure, the bottom emission structure will be described as an example.

For example, in the case of the bottom emission structure, the first electrode layer 250 may be a conductive material which transmits or semi-transmits light, and the second electrode layer 270 may be reflective metal.

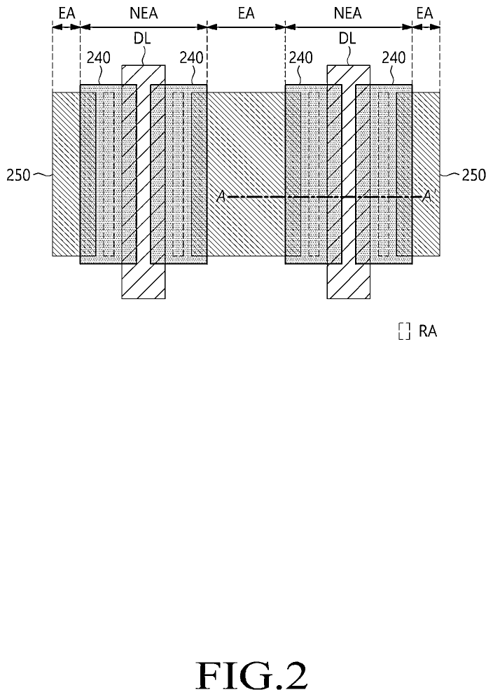

FIG. 2 is a view illustrating a schematic planar structure of a pixel structure disposed in a display panel of a display device according to an example embodiment of the present disclosure.

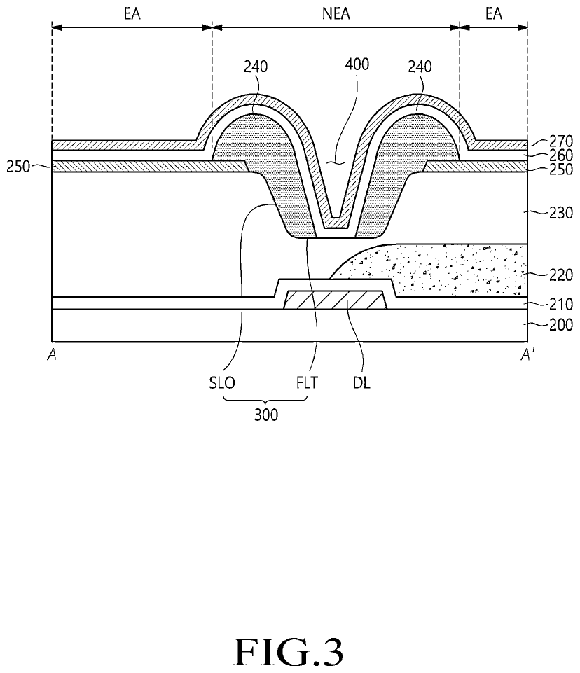

Referring to FIG. 2, the display device 100 according to the example embodiment of the present disclosure includes a plurality of subpixels. Each subpixel includes an emitting area EA which emits light from a light emitting layer 260 (see, e.g., FIG. 3) for display, and a non-emitting area NEA other than the emitting area EA.

The display device 100 according to the example embodiment of the present disclosure may include a bank layer 240 to partition each subpixel.

The emitting area EA may be defined by the opening area of the bank layer 240 (see, e.g., the emitting area EA in the middle region of FIG. 2).

In other words, the emitting area EA of the subpixel may be substantially the same as the opening area of the bank layer 240.

In one or more aspects of the present disclosure, being substantially the same may represent the same degree in consideration of a minute difference due to an error in a process.

The subpixel structure of the display device 100 according to the example embodiment of the present disclosure may also include a “signal line connection structure” related with that each subpixel is connected to various signal lines such as a data line DL, a gate line (not shown), a driving voltage line (not shown) and a reference voltage line (not shown).

The signal lines may include not only the data line DL for supplying a data voltage (Vdata) to each subpixel and the gate line (not shown) for supplying a scan signal but also the reference voltage line (not shown) for supplying a reference voltage (Vref) to each subpixel and the driving voltage line (not shown) for supplying a driving voltage (EVDD).

In the display device 100 according to the example embodiment of the present disclosure, pixels disposed in emitting areas EA of the display device 100 may include subpixels of different colors to implement the color of an image.

The subpixels may include a red subpixel (R), a green subpixel (G) and a blue subpixel (B).

Each of the subpixels may include a white subpixel.

Referring to FIG. 2, a first electrode layer 250 may be disposed in each subpixel disposed in the display panel 110 of the display device 100 according to the example embodiment of the present disclosure, and the data line DL may be located between first electrode layers 250.

In order to partition each subpixel, the bank layer 240 which overlaps at least a partial area of the data line DL and at least a partial area of the first electrode layer 250 may be included.

In FIG. 2, among light emitted from each subpixel, waveguide mode light which does not go out of the light emitting layer 260 and propagates laterally may be extracted to the front by a reflective area RA of FIG. 2.

The reflective area RA of FIG. 2 may overlap the bank layer 240 and at the same time may not overlap the data line DL and the first electrode layer 250.

The reflective area RA of FIG. 2 is illustrated only on both sides of the first electrode layer 250, but is not limited thereto. The reflective area RA may surround the entire emitting area EA, may not be continuous (for example, the reflective area RA may have an island shape), or may surround only three sides of the emitting area EA.

FIG. 3 is an example of a cross-sectional view taken along the line A-A′ of FIG. 2.

Details regarding the data line DL, the first electrode layer 250, and the bank layer 240 of FIG. 3 may be substantially the same as details regarding the data line DL, the first electrode layer 250, and the bank layer 240 described above with reference to FIG. 2.

Referring to FIG. 3, the display device 100 according to the example embodiment of the present disclosure may include a plurality of subpixels each including the emitting area EA and the non-emitting area NEA.

The display device 100 according to the example embodiment of the present disclosure may include a buffer layer 210 which is disposed on a substrate 200 and an overcoat layer 230 which is disposed on the buffer layer 210.

The overcoat layer 230 may include a concave part 300 which is located between emitting areas EA.

The concave part 300 may be composed of a flat portion FLT and a sloped portion SLO which surrounds the flat portion FLT.

The first electrode layer 250 may be disposed on the periphery of the concave part 300.

The first electrode layer 250 may include a conductive material which transmits or semi-transmits light.

For example, the first electrode layer 250 may include at least one type of transparent conductive oxide such as indium tin oxide (ITO), indium zinc oxide (IZO), indium tin zinc oxide (ITZO), zinc oxide and tin oxide, or may include translucent metal such as magnesium, silver and alloy of magnesium and silver.

In one or more aspects of the present disclosure, the periphery of the concave part 300 may be an area other than the concave part 300.

The display device 100 according to the example embodiment of the present disclosure may include the bank layer 240 which covers at least a part of the first electrode layer 250 and covers the concave part 300.

The light emitting layer 260 may be disposed on the first electrode layer 250 and the bank layer 240.

The light emitting layer 260 of the light emitting element ED may be formed by a deposition or coating method that has directionality.

For example, the light emitting layer 260 may be formed by physical vapor deposition (PVD).

The light emitting layer 260 may include a red organic light emitting layer disposed in the red subpixel (R), a green organic light emitting layer disposed in the green subpixel (G), and a blue organic light emitting layer disposed in the blue subpixel (B).

A second electrode layer 270 may be disposed on the light emitting layer 260.

The second electrode layer 270 may include reflective metal.

FIG. 3 illustrates a configuration in which the second electrode layer 270 is a single layer. However, the example embodiment of the present disclosure is not limited thereto, and the second electrode layer 270 may be composed of a multilayer.

For example, when the second electrode layer 270 is composed of a multilayer, at least one layer may include reflective metal.

For example, the second electrode layer 270 may include at least one of aluminum, neodymium, nickel, titanium, tantalum, copper, silver and aluminum alloy, but the example embodiment of the present disclosure is not limited thereto.

The bank layer 240 may include a groove part 400 which exposes at least a partial area of the overcoat layer 230.

The data line DL may be disposed on the substrate 200 and be located below the concave part 300.

The buffer layer 210 may cover the data line DL.

A color filter layer 220 may be disposed over the substrate 200 and cover at least a partial area of the data line DL.

The overcoat layer 230 may be disposed on the color filter layer 220 and the buffer layer 210 without being cut.

In this case, the overcoat layer 230 may have a level difference between an area where the color filter layer 220 is disposed and an area where the color filter layer 220 is not disposed.

For example, the overcoat layer 230 may be formed by being entirely formed on the color filter layer 220 and the buffer layer 210 and then being etched in an area between subpixels.

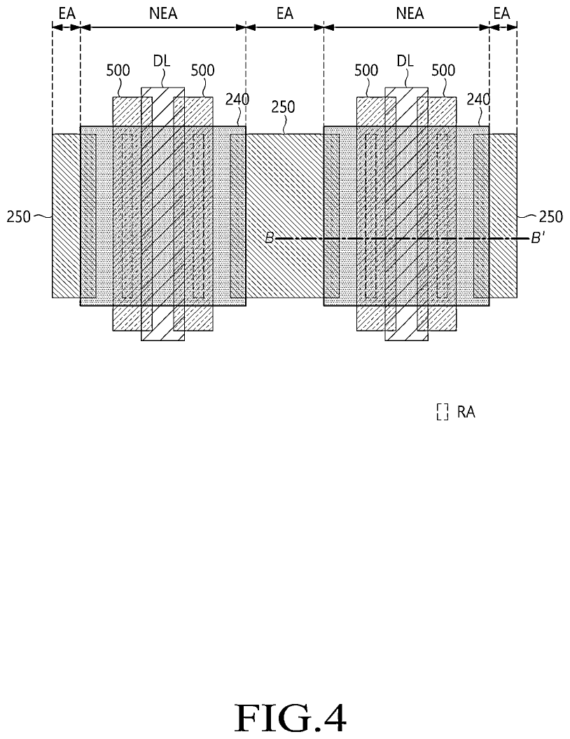

FIG. 4 is a view illustrating a schematic planar structure of a pixel structure disposed in a display panel of a display device according to another embodiment of the present disclosure.

Details regarding the data line DL, the first electrode layer 250, the bank layer 240 and the reflective area RA of FIG. 4 may be substantially the same as details regarding the data line DL, the first electrode layer 250, the bank layer 240 and the reflective area RA described above with reference to FIG. 2. Thus, repetitive descriptions may be omitted for brevity.

Referring to FIG. 4, a metal pattern layer 500 which is disposed to be spaced apart from the first electrode layer 250 and overlaps the bank layer 240 may be included.

The metal pattern layer 500 may include reflective metal.

FIG. 4 illustrates a configuration in which the metal pattern layer 500 is a single layer. However, the example embodiment of the present disclosure is not limited thereto, and the metal pattern layer 500 may be composed of a multilayer.

For example, when the metal pattern layer 500 is composed of a multilayer, at least one layer may include reflective metal.

For example, the metal pattern layer 500 may include at least one of aluminum, neodymium, nickel, titanium, tantalum, copper, silver and aluminum alloy, but the example embodiment of the present disclosure is not limited thereto.

A material constituting the metal pattern layer 500 may be substantially the same as a material constituting the second electrode layer 270, but is not necessarily limited thereto. The metal pattern layer 500 may be formed of a different material selected from reflective metals.

In the display device 100 according to the example embodiment of the present disclosure, the data line DL and the metal pattern layer 500 may overlap each other in at least a partial area, but are not limited thereto.

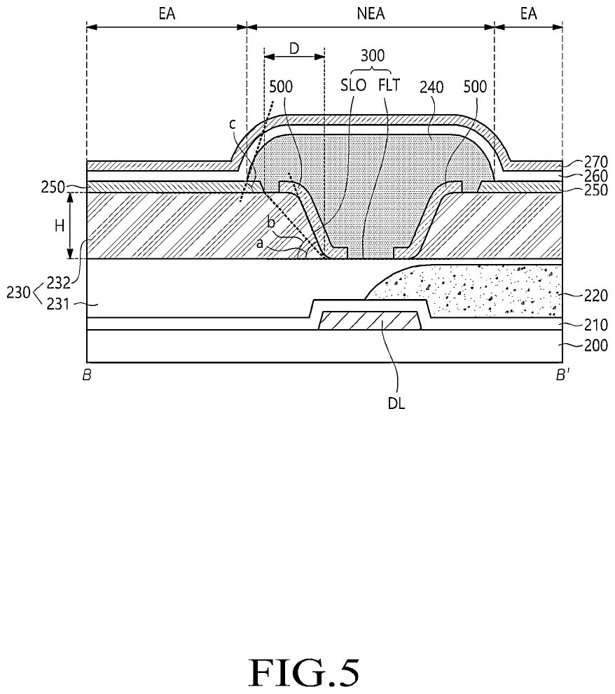

FIG. 5 is an example of a cross-sectional view taken along the line B-B′ of FIG. 4.

Details regarding the substrate 200, the buffer layer 210, the color filter layer 220, the bank layer 240, the first electrode layer 250, the light emitting layer 260 and the second electrode layer 270 of FIG. 5 may be substantially the same as details regarding the substrate 200, the buffer layer 210, the color filter layer 220, the bank layer 240, the first electrode layer 250, the light emitting layer 260 and the second electrode layer 270 described above with reference to FIG. 3. Thus, repetitive descriptions may be omitted for brevity.

Also, details regarding the metal pattern layer 500 of FIG. 5 may be substantially the same as details regarding the metal pattern layer 500 described above with reference to FIG. 4. Thus, repetitive descriptions may be omitted for brevity.

Referring to FIG. 5, by disposing the metal pattern layer 500 which covers the sloped portion SLO of the concave part 300, the extraction of waveguide mode light may be maximized to improve the light efficiency of the light emitting element ED.

In addition, even when the bank layer 240 does not include the groove part 400 in order to extract waveguide mode light, the metal pattern layer 500 may perform the role of the groove part 400.

The metal pattern layer 500 may be disposed to be spaced apart from the first electrode layer 250.

As the bank layer 240 is disposed between the metal pattern layer 500 and the first electrode layer 250, it is possible to prevent that waveguide mode light is reflected by the metal pattern layer 500, is not discharged toward the substrate 200 and is extinguished.

The bank layer 240 may be located between the metal pattern layer 500 and the first electrode layer 250. The bank layer 240 may cover an area between the metal pattern layer 500 and the first electrode layer 250.

As the bank layer 240 is located between the metal pattern layer 500 and the first electrode layer 250, it is possible to prevent a phenomenon that the first electrode layer 250 which includes a conductive material that transmits or semi-transmits light and the metal pattern layer 500 which includes a reflective material influence each other.

In the display device 100 according to the example embodiment of the present disclosure, an angle a formed between the flat portion FLT of the concave part 300 and the sloped portion SLO of the concave part 300 may be 45 degrees or more.

In one or more aspects, the angle a formed by the flat portion FLT of the concave part 300 and the sloped portion SLO of the concave part 300 is an angle a that is formed by a straight line extending from the flat portion FLT of the concave part 300 and a straight line passing through the inflection point of the sloped portion SLO of the concave part 300 and at the same time touching the sloped portion SLO of the concave part 300.

In one or more aspects of the present disclosure, an angle is an acute angle.

When the angle a formed by the flat portion FLT of the concave part 300 and the sloped portion SLO of the concave part 300 is 45 degrees or more, an angle c formed by a tangent of the bank layer 240 passing through a point where all of the first electrode layer 250, the light emitting layer 260 and the bank layer 240 meet and the periphery of the concave part 300 may be designed to be 43 degrees or less.

As the angle c formed by the tangent of the bank layer 240 passing through the point where all of the first electrode layer 250, the light emitting layer 260 and the bank layer 240 meet and the periphery of the concave part 300 is 43 degrees or less, it is possible to minimize occurrence of a dead pixel due to cut of the second electrode layer 270.

In the display device 100 according to the example embodiment of the present disclosure, an angle b formed by a line segment connecting, at a shortest distance, the boundary line of the first electrode layer 250 and a boundary line where the sloped portion SLO of the concave part 300 and the flat portion FLT of the concave part 300 meet and the flat portion FLT of the concave part 300 may be 39 degrees or more and 60 degrees or less. In other words, a line segment may connect, at a shortest distance, the boundary line of the first electrode layer 250 and a boundary line where the sloped portion SLO of the concave part 300 and the flat portion FLT of the concave part 300 meet. In this case, an angle b formed by the line segment and the flat portion FLT of the concave part 300 may be 39 degrees or more and 60 degrees or less.

The line segment may be the hypotenuse of a triangle defined by a distance D between the boundary line of the first electrode layer 250 and the boundary line where the sloped portion SLO of the concave part 300 and the flat portion FLT of the concave part 300 meet and a thickness H of a second overcoat layer 232 to be described below.

The following [General Equation 1] may be established.

H/D=tan(b) [General Equation 1]

When the angle b is 39 degrees or more and 60 degrees or less, substrate mode light and waveguide mode light may be efficiently extracted.

Referring to FIG. 5, the overcoat layer 230 may include a first overcoat layer 231 which is disposed over the substrate 200 and the second overcoat layer 232 which is disposed on the first overcoat layer 231 and includes the sloped portion SLO of the concave part 300.

The first overcoat layer 231 may be disposed on the color filter layer 220 and the buffer layer 210 without being cut.

In this case, the first overcoat layer 231 may have a level difference between an area where the color filter layer 220 is disposed and an area where the color filter layer 220 is not disposed.

The refractive index of the second overcoat layer 232 may be greater than the refractive index of the first overcoat layer 231.

When the refractive index of the second overcoat layer 232 is greater than the refractive index of the first overcoat layer 231, not only it is possible to improve extraction efficiency for waveguide mode light, but also it is possible to improve extraction efficiency for substrate mode light which is emitted from the light emitting layer 260 but is not discharged to the outside of the substrate 200.

For example, the refractive index of the first overcoat layer 231 may be 1.14 or more and 1.57 or less, and the refractive index of the second overcoat layer 232 may be 1.57 or more and 1.65 or less.

In one or more aspects, preferably, the refractive index of the first overcoat layer 231 may be 1.14 or more and 1.46 or less, and the refractive index of the second overcoat layer 232 may be 1.63 or more and 1.65 or less.

However, the example embodiment of the present disclosure is not necessarily limited thereto, and the refractive index of the second overcoat layer 232 may be equal to or less than the refractive index of the first overcoat layer 231.

For another example, the refractive indexes of the first overcoat layer 231 and the second overcoat layer 232 may be 1.57.

For still another example, the refractive index of the first overcoat layer 231 may be 1.57, and the refractive index of the second overcoat layer 232 may be 1.63.

Fresnel losses are proportional to a value obtained by dividing the refractive index of the first overcoat layer 231 by the refractive index of the second overcoat layer 232.

In order to minimize Fresnel losses, the refractive index of the second overcoat layer 232 may be designed to be greater than the refractive index of the first overcoat layer 231, and in one or more aspects, it is preferred that a value obtained by dividing the refractive index of the first overcoat layer 231 by the refractive index of the second overcoat layer 232 is 0.7 or more.

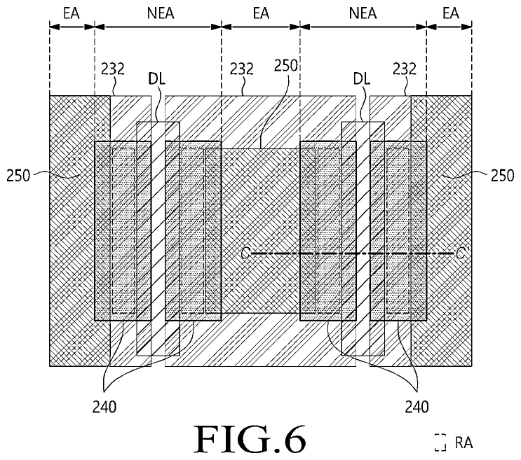

FIG. 6 is a view illustrating a schematic planar structure of a pixel structure disposed in a display panel 110 of a display device 100 according to still another example embodiment of the present disclosure.

Details regarding the bank layer 240, the first electrode layer 250, the data line DL and the reflective area RA of FIG. 6 may be substantially the same as details regarding the bank layer 240, the first electrode layer 250, the data line DL and the reflective area RA described above with reference to FIG. 2.

Also, details regarding the second overcoat layer 232 of FIG. 6 may be substantially the same as details regarding the second overcoat layer 232 described above with reference to FIG. 5. Thus, repetitive descriptions may be omitted for brevity.

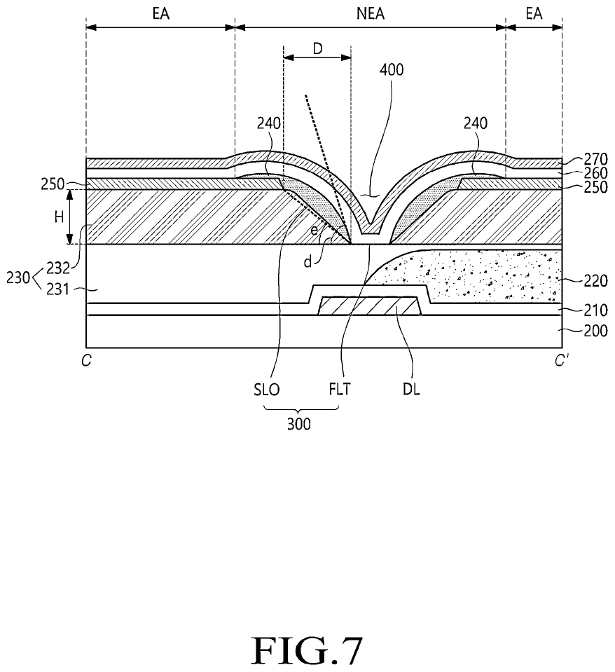

FIG. 7 is an example of a cross-sectional view taken along the line C-C′ of FIG. 6.

Details regarding the substrate 200, the buffer layer 210, the color filter layer 220, the bank layer 240, the first electrode layer 250, the light emitting layer 260, the second electrode layer 270, the groove part 400, and the data line DL of FIG. 7 may be substantially the same as details regarding the substrate 200, the buffer layer 210, the color filter layer 220, the bank layer 240, the first electrode layer 250, the light emitting layer 260, the second electrode layer 270, the groove part 400, and the data line DL described above with reference to FIG. 2. Thus, repetitive descriptions may be omitted for brevity.

Also, details regarding the first overcoat layer 231 and the second overcoat layer 232 of FIG. 7 may be substantially the same as details regarding the first overcoat layer 231 and the second overcoat layer 232 described above with reference to FIG. 5. Thus, repetitive descriptions may be omitted for brevity.

Referring to FIG. 7, the overcoat layer 230 of the display device 100 according to the example embodiment of the present disclosure may include the first overcoat layer 231 and the second overcoat layer 232, and the refractive index of the second overcoat layer 232 may be greater than the refractive index of the first overcoat layer 231.

When the refractive index of the second overcoat layer 232 is greater than the refractive index of the first overcoat layer 231, not only it is possible to improve extraction efficiency for waveguide mode light, but also it is possible to improve extraction efficiency for substrate mode light which is emitted from the light emitting layer 260 but is not discharged to the outside of the substrate 200.

For example, the refractive index of the first overcoat layer 231 may be 1.14 or more and 1.57 or less, and the refractive index of the second overcoat layer 232 may be 1.57 or more and 1.65 or less.

In one or more aspects, preferably, the refractive index of the first overcoat layer 231 may be 1.14 or more and 1.46 or less, and the refractive index of the second overcoat layer 232 may be 1.63 or more and 1.65 or less.

However, the example embodiment of the present disclosure is not necessarily limited thereto, and the refractive index of the second overcoat layer 232 may be equal to or less than the refractive index of the first overcoat layer 231.

For another example, the refractive indexes of the first overcoat layer 231 and the second overcoat layer 232 may be 1.57.

For still another example, the refractive index of the first overcoat layer 231 may be 1.57, and the refractive index of the second overcoat layer 232 may be 1.63.

Fresnel losses are proportional to a value obtained by dividing the refractive index of the first overcoat layer 231 by the refractive index of the second overcoat layer 232.

In order to minimize Fresnel losses, the refractive index of the second overcoat layer 232 may be designed to be greater than the refractive index of the first overcoat layer 231, and in one or more aspects, it is preferred that a value obtained by dividing the refractive index of the first overcoat layer 231 by the refractive index of the second overcoat layer 232 is 0.7 or more.

Referring to FIG. 7, the bank layer 240 may include the groove part 400 which exposes at least a partial area of the first overcoat layer 231, but is not necessarily limited thereto. The bank layer 240 may not expose the first overcoat layer 231.

In the case where the bank layer 240 includes the groove part 400, since, when forming the second electrode layer 270 on the light emitting layer 260, the second electrode layer 270 is formed according to the shape of the groove part 400, it is possible to efficiently extract substrate mode light and waveguide mode light.

In one or more aspects, it is preferred that, in the groove part 400 of the bank layer 240, an angle d formed by the upper surface of the first overcoat layer 231 and the bank layer 240 is 45 degrees or less.

In one or more aspects, the angle d formed by the upper surface of the first overcoat layer 231 and the bank layer 240 is an angle formed by the upper surface of the first overcoat layer 231 and a straight line passing through the inflection point of the bank layer 240 in the groove part 400 and at the same time touching the bank layer 240.

When the angle d formed by the upper surface of the first overcoat layer 231 and the bank layer 240 in the groove part 400 of the bank layer 240 is 45 degrees or less, it is possible to efficiently extract substrate mode light and waveguide mode light.

Accordingly, in the present example embodiment, the greatest height of the bank layer 240 may be lower than those in the other example embodiments, and the bank layer 240 may be formed thinner than the bank layer 240 in the other example embodiments.

In the present example embodiment, the distance D between the boundary line of the first electrode layer 250 and the boundary line where the sloped portion SLO of the concave part 300 and the flat portion FLT of the concave part 300 meet may be formed longer than those in the other example embodiments.

As shown in FIG. 6, the width of the reflective area RA in the present example embodiment may be formed larger than those in the other example embodiments.

The end of the second overcoat layer 232 is in contact with the end of the bank layer 240 on the first overcoat layer 231 and on the boundary line where the sloped portion SLO of the concave part 300 and the flat portion FLT of the concave part 300 meet.

In the display device 100 according to the example embodiment of the present disclosure, an angle e formed by a line segment connecting, at a shortest distance, the boundary line of the first electrode layer 250 and a boundary line where the sloped portion SLO of the concave part 300 and the flat portion FLT of the concave part 300 meet and the flat portion FLT of the concave part 300 may be 12 degrees or more and 36 degrees or less.

The line segment may be the hypotenuse of a triangle defined by a distance D between the boundary line of the first electrode layer 250 and the boundary line where the sloped portion SLO of the concave part 300 and the flat portion FLT of the concave part 300 meet and a thickness H of a second overcoat layer 232.

The following [General Equation 2] may be established.

H/D=tan(e) [General Equation 2]

When the angel e is 12 degrees or more and 36 degrees or less, it is possible to efficiently extract substrate mode light and waveguide mode light.

Various examples and aspects of the present disclosure are described below. These are provided as examples, and do not limit the scope of the present disclosure.

A display device according to one or more example embodiments of the present disclosure may include: a substrate; a plurality of subpixels each of which includes an emitting area and a non-emitting area; an overcoat layer disposed over the substrate, and having a concave part located between emitting areas; a first electrode layer disposed on a periphery of the concave part; a metal pattern layer disposed to cover a sloped portion of the concave part; and a bank layer covering the concave part, and disposed on the metal pattern layer.

In the display device according to the one or more example embodiments of the present disclosure, the first electrode layer and the metal pattern layer may be disposed to be spaced apart from each other.

In the display device according to the one or more example embodiments of the present disclosure, the bank layer may cover at least a part of the first electrode layer, and may be located between the first electrode layer and the metal pattern layer.

In the display device according to the one or more example embodiments of the present disclosure, an angle formed by a flat portion of the concave part and the sloped portion of the concave part may be 45 degrees or more.

In the display device according to the one or more example embodiments of the present disclosure, the display device may further include a light emitting layer disposed on the first electrode layer and the bank layer, wherein an angle formed by a tangent of the bank layer passing through a point where all of the first electrode layer, the light emitting layer and the bank layer meet and the periphery of the concave part may be 43 degrees or less.

In the display device according to the one or more example embodiments of the present disclosure, a line segment may connect, at a shortest distance, a boundary line of the first electrode layer and a boundary line where the sloped portion of the concave part and a flat portion of the concave part meet, and an angle formed by the line segment and the flat portion of the concave part may be 39 degrees or more and 60 degrees or less.

In the display device according to the one or more example embodiments of the present disclosure, the overcoat layer may include a first overcoat layer which is disposed over the substrate and a second overcoat layer which is disposed on the first overcoat layer and includes the sloped portion of the concave part, and a refractive index of the second overcoat layer may be greater than a refractive index of the first overcoat layer.

In the display device according to the one or more example embodiments of the present disclosure, a value obtained by dividing the refractive index of the first overcoat layer by the refractive index of the second overcoat layer may be 0.7 or more.

In the display device according to the one or more example embodiments of the present disclosure, the display device may further include a data line disposed on the substrate, and located below the concave part.

In the display device according to the one or more example embodiments of the present disclosure, the display device may further include a color filter layer disposed over the substrate, and covering at least a partial area of the data line.

A display device according to one or more example embodiments of the present disclosure may include: a substrate; a plurality of subpixels each of which includes an emitting area and a non-emitting area; an overcoat layer disposed over the substrate, and having a concave part located between emitting areas; a first electrode layer disposed on a periphery of the concave part; and a bank layer covering a sloped portion of the concave part, wherein the overcoat layer may include a first overcoat layer which is disposed over the substrate and a second overcoat layer which is disposed on the first overcoat layer and includes the sloped portion of the concave part, and wherein a refractive index of the second overcoat layer may be greater than a refractive index of the first overcoat layer.

In the display device according to the one or more example embodiments of the present disclosure, the refractive index of the first overcoat layer may be 1.14 or more and 1.46 or less, and the refractive index of the second overcoat layer may be 1.63 or more and 1.65 or less.

In the display device according to the one or more example embodiments of the present disclosure, a value obtained by dividing the refractive index of the first overcoat layer by the refractive index of the second overcoat layer may be 0.7 or more.

In the display device according to the one or more example embodiments of the present disclosure, the bank layer may include a groove part which exposes at least a partial area of the first overcoat layer.

In the display device according to the one or more example embodiments of the present disclosure, an angle formed by an upper surface of the first overcoat layer and the bank layer in the groove part of the bank layer may be 45 degrees or less.

In the display device according to the one or more example embodiments of the present disclosure, a line segment may connect, at a shortest distance, a boundary line of the first electrode layer and a boundary line where the sloped portion of the concave part and a flat portion of the concave part meet, and an angle formed by the line segment and the flat portion of the concave part is 12 degrees or more and 36 degrees or less.

In the display device according to the one or more example embodiments of the present disclosure, the display device may further include a data line disposed on the substrate, and located below the concave part.

In the display device according to the one or more example embodiments of the present disclosure, the display device may further include a color filter layer disposed over the substrate, and covering at least a partial area of the data line.

A display device according to one or more example embodiments of the present disclosure may include: a substrate; a plurality of subpixels each of which includes an emitting area and a non-emitting area; an overcoat layer disposed over the substrate, and having a concave part located between emitting areas; a first electrode layer disposed on the overcoat layer; a bank layer covering at least a portion of the first electrode layer and at least a portion of the concave part; and a light emitting layer covering at least a part of the first electrode layer and at least a part of the bank layer, wherein at least a part of the light emitting layer may overlap the concave part.

In the display device according to the one or more example embodiments of the present disclosure, the display device may further include a second electrode layer disposed on the light emitting layer, wherein the first electrode layer does not overlap the concave part of the overcoat layer; and at least a part of the second electrode layer overlaps the concave part of the overcoat layer.

The above description has been presented to enable any person skilled in the art to make and use the technical ideas and features of the present disclosure, and has been provided in the context of a particular application and its requirements. Various modifications, additions and substitutions to the described embodiments will be readily apparent to those skilled in the art, and the general principles provided herein may be applied to other embodiments and applications without departing from the spirit and scope of the present disclosure. The above description and the accompanying drawings provide an example of the technical ideas and features of the present disclosure for illustrative purposes only. That is, the disclosed embodiments are intended to illustrate examples of the scope of the technical ideas and features of the present disclosure. The scope of protection of the present disclosure should be construed based on the following claims, and all technical ideas and features within the scope of equivalents thereof should be construed as being included within the scope of the present disclosure.

What is claimed is:

1. A display device, comprising:
a substrate;
a plurality of subpixels each of which includes an emitting area and a non-emitting area;
an overcoat layer disposed over the substrate, and having a concave part located between emitting areas;
a first electrode layer disposed on a periphery of the concave part;
a metal pattern layer disposed to cover a sloped portion of the concave part; and
a bank layer covering the concave part, and disposed on the metal pattern layer.

2. The display device of claim 1, wherein the first electrode layer and the metal pattern layer are disposed to be spaced apart from each other.

3. The display device of claim 1, wherein the bank layer covers at least a part of the first electrode layer, and is located between the first electrode layer and the metal pattern layer.

4. The display device of claim 1, wherein an angle formed by a flat portion of the concave part and the sloped portion of the concave part is 45 degrees or more.

5. The display device of claim 1, further comprising:
a light emitting layer disposed on the first electrode layer and the bank layer,
wherein an angle formed by a tangent of the bank layer passing through a point where all of the first electrode layer, the light emitting layer and the bank layer meet and the periphery of the concave part is 43 degrees or less.

6. The display device of claim 1, wherein a line segment connects, at a shortest distance, a boundary line of the first electrode layer and a boundary line where the sloped portion of the concave part and a flat portion of the concave part meet, and an angle formed by the line segment and the flat portion of the concave part is 39 degrees or more and 60 degrees or less.

7. The display device of claim 1, wherein
the overcoat layer includes a first overcoat layer which is disposed over the substrate and a second overcoat layer which is disposed on the first overcoat layer and includes the sloped portion of the concave part, and
a refractive index of the second overcoat layer is greater than a refractive index of the first overcoat layer.

8. The display device of claim 7, wherein a value obtained by dividing the refractive index of the first overcoat layer by the refractive index of the second overcoat layer is 0.7 or more.

9. The display device of claim 1, further comprising:
a data line disposed on the substrate, and located below the concave part.

10. The display device of claim 9, further comprising:
a color filter layer disposed over the substrate, and covering at least a partial area of the data line.

11. A display device, comprising:
a substrate;
a plurality of subpixels each of which includes an emitting area and a non-emitting area;
an overcoat layer disposed over the substrate, and having a concave part located between emitting areas;
a first electrode layer disposed on a periphery of the concave part; and
a bank layer covering a sloped portion of the concave part,
wherein the overcoat layer includes a first overcoat layer which is disposed over the substrate and a second overcoat layer which is disposed on the first overcoat layer and includes the sloped portion of the concave part, and
wherein a refractive index of the second overcoat layer is greater than a refractive index of the first overcoat layer.

12. The display device of claim 11, wherein the refractive index of the first overcoat layer is 1.14 or more and 1.46 or less, and the refractive index of the second overcoat layer is 1.63 or more and 1.65 or less.

13. The display device of claim 11, wherein a value obtained by dividing the refractive index of the first overcoat layer by the refractive index of the second overcoat layer is 0.7 or more.

14. The display device of claim 11, wherein the bank layer includes a groove part which exposes at least a partial area of the first overcoat layer.

15. The display device of claim 14, wherein an angle formed by an upper surface of the first overcoat layer and the bank layer in the groove part of the bank layer is 45 degrees or less.

16. The display device of claim 11, wherein a line segment connects, at a shortest distance, a boundary line of the first electrode layer and a boundary line where the sloped portion of the concave part and a flat portion of the concave part meet, and
an angle formed by the line segment and the flat portion of the concave part is 12 degrees or more and 36 degrees or less.

17. The display device of claim 11, further comprising:
a data line disposed on the substrate, and located below the concave part.

18. The display device of claim 17, further comprising:
a color filter layer disposed over the substrate, and covering at least a partial area of the data line.

19. A display device, comprising:
a substrate;
a plurality of subpixels each of which includes an emitting area and a non-emitting area;
an overcoat layer disposed over the substrate, and having a concave part located between emitting areas;
a first electrode layer disposed on the overcoat layer;
a bank layer covering at least a portion of the first electrode layer and at least a portion of the concave part; and
a light emitting layer covering at least a part of the first electrode layer and at least a part of the bank layer, wherein at least a part of the light emitting layer overlaps the concave part.

20. The display device of claim 19, further comprising a second electrode layer disposed on the light emitting layer,
wherein:
the first electrode layer does not overlap the concave part of the overcoat layer; and
at least a part of the second electrode layer overlaps the concave part of the overcoat layer.

21. The display device of claim 19, further comprising a reflective area,
wherein the reflective area overlaps the bank layer and does not overlap the first electrode layer.
